(19) United States
(12) Patent Application Publication
(10) Pub. No.: US 2025/0011979 A1
(43) Pub. Date: Jan. 9, 2025

(54) GLASS CLOTH, GLASS CLOTH PRODUCTION METHOD, PREPREG, AND PRINTED WIRING BOARD

(71) Applicant: ASAHI KASEI KABUSHIKI KAISHA, Tokyo (JP)

(72) Inventor: Yuka FUKAYA, Tokyo (JP)

(73) Assignee: ASAHI KASEI KABUSHIKI KAISHA, Tokyo (JP)

(21) Appl. No.: 18/711,275

(22) PCT Filed: Nov. 11, 2022
(86) PCT No.: PCT/JP2022/042124

§ 371 Date: May 17, 2024

(30) Foreign Application Priority Data
Nov. 18, 2021 (JP) 2021-187919

(51) Int. Cl. D03D 15/267; B29B 11/16; B29C 70/22; B29K 309/08; C03C 17/32

(52) U.S. Cl. CPC D03D 15/267; B29B 11/16; B29C 70/22; B29K 2309/08; C03C 17/32; D10B 2505/02

(57) ABSTRACT

The present disclosure provides a glass cloth including glass yarns composed of a plurality of glass filaments, woven as warp and weft yarns, and surface-treated with a surface treatment agent, wherein
the glass cloth contains a predetermined region, and
in the region, the following formula (1) is greater than 0 and 0.14 or less:

$$( E 1 / T 1 ) / ( W 1 / L 1 ) \qquad ( 1 )$$

wherein E1 represents a second repetition bending rigidity (N·cm²/cm) per unit length between curvatures of 0.5 and +1.5 cm⁻¹ during a second repetition of bending with a curvature of 2.5 cm⁻¹,
T1 represents a thickness (cm) of the region,
L1 represents an insertion interval (cm) of the warp yarns,
W1 represents a warp width (cm), and
bending is carried out so as to create a valley that forms a valley bottom line along a weft direction.

### FIELD

The present invention relates to a glass cloth, a glass cloth production method, a prepreg, and a printed wiring board.

### BACKGROUND

Glass cloths are widely used as base materials for printed wiring boards used in electronic devices. In recent years, as information terminals such as smartphones have become more sophisticated and have faster communication speeds, printed wiring boards with lower dielectric properties (for example, lower dielectric constant and lower dielectric loss tangent) are on trend. In order to meet the demand for printed wiring boards with lower dielectric properties, regarding the materials constituting the base materials, a glass cloth treated with a silane coupling agent and a low dielectric resin such as polyphenylene ether (hereinafter also referred to as a “matrix resin”) are used, and a method of impregnating the glass cloth with the low dielectric resin is adopted.

Since low dielectric resins such as polyphenylene ether tend to have higher viscosity than conventionally known epoxy resins, etc., resin-unimpregnated portions (voids) of the glass fiber bundle in the substrate are likely to be formed, resulting in CAF (Conductive Anodic Filament) failure. Thus, it is necessary to improve CAF resistance by further increasing the resin impregnation properties.

In general, the improvement of the property of resin impregnation into a glass cloth is carried out as fiber opening processing of the glass cloth, such as a method using a columnar flow or a spray flow, a method using a vibro washer, or a method using high frequency vibration using a liquid as a medium. As methods for improving the resin impregnation properties, a fiber opening method of immersing a glass cloth in a colloidal silica-containing liquid (refer to Patent Literature 1), a method of using a colloidal silica-containing liquid as a glass fiber sizing agent (refer to Patent Literature 2), and a method of immersing a glass cloth in an aqueous dispersion of resin fine particles and elastomer fine particles (refer to Patent Literature 3) have been proposed.

### CITATION LIST

### Patent Literature

[PTL 1] Japanese Unexamined Patent Publication (Kokai) No. 2010-84236

[PTL 2] Japanese Unexamined Patent Publication (Kokai) No. 9-208268

[PTL 3] Japanese Unexamined Patent Publication (Kokai) No. 2018-115225

### SUMMARY

### Technical Problem

As the background for glass cloths, there has been a strong desire to further improve the impregnation properties of high viscosity and low dielectric resins such as polyphenylene ether. Though nanoparticles are adhered to glass cloths in the methods described in Patent Literature 1 to 3, generally, it is desirable that nanoparticles such as colloidal silica not be included, since there are concerns that nanoparticles may be harmful to the environment and the human body. Specifically, the methods described in Patent Literature 1 to 3 have room for improvement in terms of the burden on the environment and the human body.

The present invention has been achieved in light of the problems described above, and an object thereof is to provide a glass cloth which has a low impact on the environment and the human body, and which has suitable impregnation properties with low dielectric resins. Another object of the present invention is to provide a prepreg and a printed wiring board using the glass cloth.

### Solution to Problem

As a result of investigation in order to achieve the objects described above, the present inventors have discovered that by providing a specific region to a glass cloth, the above objects can be achieved, and have completed the present invention.

Specifically, the aspects of the present invention are as described below.

[1]

A glass cloth comprising glass yarns composed of a plurality of glass filaments, woven as warp and weft yarns, and surface-treated with a surface treatment agent, wherein
the glass cloth contains a predetermined region, and
in the region, the following formula (1) is greater than 0 and 0.14 or less:

$$( E 1 / T 1 ) / ( W 1 / L 1 ) \qquad ( 1 )$$

wherein E1 represents a second repetition bending rigidity (N·cm²/cm) per unit length between curvatures of 0.5 and +1.5 cm⁻¹ during a second repetition of bending with a curvature of 2.5 cm⁻¹,
T1 represents a thickness (cm) of the region,
L1 represents an insertion interval (cm) of the warp yarns,
W1 represents a warp width (cm), and
bending is carried out so as to create a valley that forms a valley bottom line along a weft direction.
   [2]

The glass cloth according to Aspect 1, wherein the formula (1) is greater than 0 and 0.13 or less.

[3]

The glass cloth according to Aspect 1 or 2, wherein the thickness T1 of the region is 0.002 to 0.013 cm.

[4]

The glass cloth according to any one of Aspects 1 to 3, wherein the insertion interval L1 of the warp yarns is 0.021 to 0.25 cm.

[5]

The glass cloth according to any one of Aspects 1 to 4, wherein an amount of fine particles adhered to the region is 100 particles/μm or less.

[6]

The glass cloth according to any one of Aspects 1 to 5, wherein the surface treatment agent contains a silane coupling agent having a radical-reactive unsaturated double bond.

[7]

The glass cloth according to any one of Aspects 1 to 6, wherein a number of fuzz having a length of 1 mm or more observed when a tension of 100 N/1000 mm is applied by roll-to-roll is 10 pieces/m² or less, and a weft distortion rate is 4% or less.

[8]

The glass cloth according to any one of Aspects 1 to 7, wherein the glass cloth contains a region where the following formula (2) satisfies greater than 0 and 0.14 or less:

$$( E 2 / T 2 ) / ( W 2 / L 2 ) \qquad ( 2 )$$

wherein E2 represents a second repetition bending rigidity (N·cm²/cm) per unit length between curvatures of 0.5 and +1.5 cm⁻¹ during a second repetition of bending with a curvature of 2.5 cm⁻¹,
T2 represents a thickness (cm) of the region,
L2 represents an insertion interval (cm) of the weft yarns,
W2 represents a weft width (cm), and
bending is carried out so as to create a valley that forms a valley bottom line along a warp direction.
   [9]

The glass cloth according to Aspect 8, wherein the formula (2) is greater than 0 and 0.13 or less.

[10]

The glass cloth according to Aspect 8 or 9, wherein the thickness T2 of the region is 0.002 to 0.013 cm.

[11]

The glass cloth according to any one of Aspects 8 to 10, wherein the insertion interval L2 of the weft yarns is 0.021 to 0.25 cm.

[12]

The glass cloth according to any one of Aspects 1 to 11, wherein an amount of fine particles adhered to the region is 0 particles/μm.

[13]

The glass cloth according to Aspect 5 or 12, wherein the fine particles are inorganic fine particles and/or organic fine particles having a diameter of 3 μm or less.

[14]

The glass cloth according to Aspect 13, wherein the inorganic fine particles are at least one selected from the group consisting of colloidal silica, crystalline silica, alumina, and boron nitride, and
the organic fine particles are at least one selected from the group consisting of a polyphenylene ether resin, an epoxy resin, and a styrenic elastomer.
   [15]

A prepreg, comprising the glass cloth according to any one of Aspects 1 to 14, and a matrix resin composition, with which the glass cloth is impregnated.

[16]

A printed wiring board, comprising the glass cloth according to any one of Aspects 1 to 14, and a cured product of a matrix resin composition, with which the glass cloth is impregnated.

[17]

A glass cloth production method for the glass cloth according to any one of Aspects 1 to 13, comprising the step of:
spraying fine particles of dry ice to perform fiber-opening processing.
   [18]

The glass cloth production method according to Aspect 17, wherein the fiber-opening processing is performed by bending with a radius of curvature of 2.5 mm or less.

### Advantageous Effects of Invention

According to the present invention, a glass cloth which can obtain suitable impregnation properties with low dielectric resins can be provided. Furthermore, according to the present invention, a prepreg and a printed wiring board using the glass cloth can also be provided.

### BRIEF DESCRIPTION OF DRAWINGS

FIG. 1 is a view showing an example of a method for measuring the bending rigidity of a glass cloth according to an embodiment of the present invention.

FIG. 2 is a view showing an example of a method for measuring the bending rigidity of a glass cloth according to an embodiment of the present invention.

### DESCRIPTION OF EMBODIMENTS

The embodiments (hereinafter referred to as “the present embodiment”) of the present invention will be described below. However, the present invention is not limited to the following embodiments, and various changes can be made within the scope of the spirit thereof. In the present embodiment, numerical ranges described using “to” include the numbers written before and after “to.” Furthermore, in the present embodiment, in numerical ranges described in stages, the upper limit or lower limit described in one numerical range can be replaced with the upper or lower limit of another numerical range described in stages. Further, in the present embodiment, the upper limit value or lower limit value described in a certain numerical range can also be replaced with a value shown in the Examples.

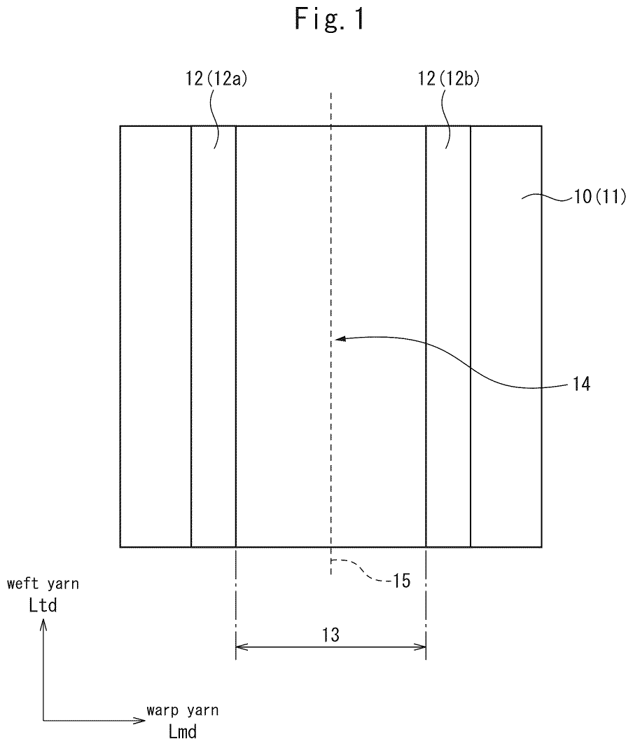

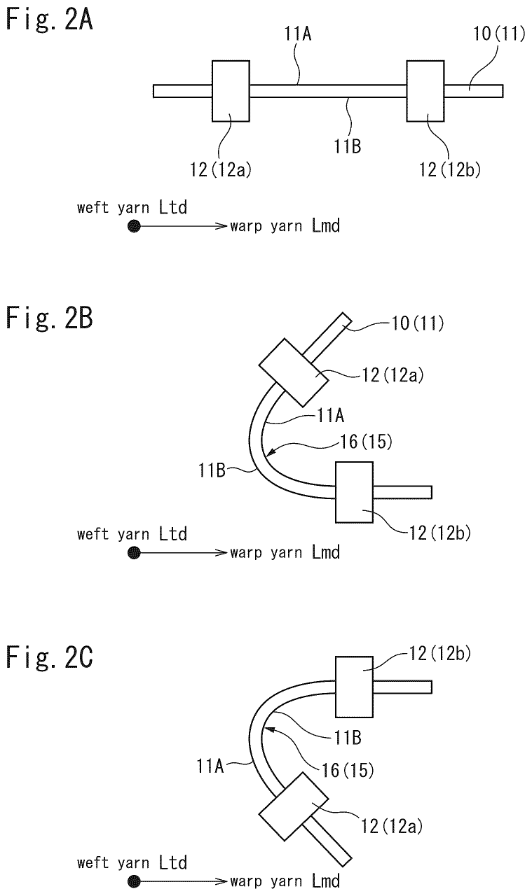

In the contents shown in FIGS. 1 and 2, the scale, shape, and length may be exaggerated for additional clarity.

### [Schematic Configuration]

The glass cloth of the present embodiment comprises glass yarns composed of a plurality of glass filaments, woven as warp and weft yarns, and surface-treated with a surface treatment agent, wherein
the glass cloth contains a predetermined region, and
in the region, the following formula (1) is greater than 0 and 0.14 or less:

$$( E 1 / T 1 ) / ( W 1 / L 1 ) . \qquad ( 1 )$$

In the formula, E1 represents a second repetition bending rigidity (N·cm²/cm) per unit length between curvatures of 0.5 and +1.5 cm⁻¹ during a second repetition of bending with a curvature of 2.5 cm⁻¹, T1 represents a thickness (cm) of the region, L1 represents a warp insertion interval (cm), and W1 represents a warp width (cm).

More specifically, regarding E1 in formula (1), when
first bending from a curvature of 0 to a curvature of +2.5 cm⁻¹,
second bending from a curvature of +2.5 cm⁻¹, through a curvature of 0, to a curvature of −2.5 cm⁻¹, and
third bending from a curvature of −2.5 cm⁻¹, through a curvature of 0, to a curvature of +2.5 cm⁻¹
are performed, E1 represents the above bending rigidity obtained between a curvature of 0.5 and a curvature +1.5 cm⁻¹ in the third bending.

Formula (1) is satisfied when E1/T1 is relatively small and W1/L1 is relatively large.

In order for E1/T1 to be relatively small, the bending rigidity E1 must be relatively small and thickness T1 must be relatively large. The bending rigidity E1 is a value that increases as the rigidity of the region increases. Thus, E1/T1 being relatively small means that even if the region has a certain degree of thickness, the rigidity thereof is small (i.e., flexible).

Conversely, in order for W1/L1 to be relatively large, the yarn width W1 must be relatively large and the insertion interval L1 must be relatively small.

As an example of the relationship between E1/T1 and W1/L1, when the bending rigidity E1 increases from the viewpoint of meeting the demand for increasing W1/L1, it is difficult to meet the demand for reducing E1/T1. Conversely, from the viewpoint of meeting the demand for reducing E1/T1, lower warp and weft insertion densities are advantageous to reduce bending rigidity E1, but in this case, it is difficult to meet the demand for increasing W1/L1.

As an example from the viewpoint of impregnation properties with matrix resins, since the region which meets the demand for reducing E1/T1 has a small bending rigidity relative to the thickness, it is likely to be advantageous in obtaining suitable impregnation properties with the matrix resin. In the region, it is preferable that the bending rigidity E1 be low. This leads to reduced adhesion between filaments due to the sizing agent and the silane coupling agent, and as a result, the impregnation properties are improved. Conversely, in the region which meets the demand for increasing W/L1, when L1 is small, impregnation of the matrix resin becomes unlikely.

The present inventors focused on E1/T1 and W1/L1, which sometimes have contradictory viewpoints. As a result of rigorous investigation, the present inventors focused on not only a small E1/T1 but also W1/L1 in order to obtain suitable impregnation properties with the matrix resin, and have discovered that based on formula (1), which combines W1/L1 with E1/T1, suitable impregnation properties with matrix resin can be achieved overall.

Bending with a curvature of +2.5 cm⁻¹ and a curvature of −2.5 cm⁻¹ is outside the range of elastic deformation of the region. Specifically, the region can be plastically deformed by first bending with a curvature of +2.5 cm⁻¹.

Since the first bending is an initial bending to one surface side of the region and the second bending is an initial bending to the other surface side of the region, the initial bending loads for the first bending and the second bending are greater than those for subsequent bending. The significance of focusing on second repetition bending rigidity (rigidity during the third bending described above) is that because of being less susceptible to the influence of the initial load required for first and second bending, the bending rigidity per unit length during the bending process from a curvature of 0.5 to a curvature of +1.5 cm⁻¹ can be accurately measured. In this regard, bending rigidity can be measured at the fourth bending, at the fifth bending, etc., after the third bending. As the bending number increases, the bending tendency of the region increases, and thus, the bending rigidity tends to decrease, and in this case, it becomes difficult to accurately obtain the bending rigidity in the region required for formula (1).

In addition to the foregoing, in the present embodiment, focusing on the “second repetition bending rigidity” is significant from the following viewpoints.

Specifically, the “second repetition bending” of the present embodiment is bending which is performed on the glass cloth to be measured after it has been bent in advance in preparation for measurement (corresponding to the first bending and second bending described above). By focusing on the “second repetition bending” performed after such preliminary bending, it is possible to accurately measure the predetermined rigidity, which is an object of the present embodiment. The above viewpoints also apply to formula (2).

The region can be at least a part of the total region of the glass cloth, and this can also be said to mean that at least a part of the glass cloth satisfies formula (1). In particular, when the region is the entire region of the glass cloth, it can be said that the entire glass cloth satisfies formula (1). The size of the region needs only to be less than or equal to the total area of the glass cloth, and the shape thereof is not limited. The region may have a circular shape or a rectangular shape.

Formula (1) is preferably 0.13 or less, more preferably 0.12 or less, and particularly preferably 0.10 or less from the viewpoint of easily realizing a glass cloth with suitable resin impregnation properties.

From the same viewpoint as formula (1), it is preferable that the following formula (2) be greater than 0 and 0.14 or less:

$$( E 2 / T 2 ) / ( W 2 / L 2 ) \qquad ( 2 )$$

wherein E2 represents a second repetition bending rigidity (N·cm²/cm) per unit length between curvatures of 0.5 and +1.5 cm⁻¹ during a second repetition of bending with a curvature of 2.5 cm⁻¹, T2 represents the thickness (cm) of the region, L2 represents the insertion interval (cm) of the weft yarns, and W2 represents the weft width (cm).

Formula (2) is preferably 0.13 or less, more preferably 0.12 or less, and particularly preferably 0.10 or less from the viewpoint of easily realizing a glass cloth with suitable resin impregnation properties.

Basically, when there is no anisotropy between warp and the weft yarns (when a value between L1 and L2 is within ±5% and the warp and weft yarns have the same number of filaments), since the warp is constantly under tension during the fiber-opening step, the adhesion between filaments is difficult to separate, and E1 tends to have a greater value than E2. Whether or not there is anisotropy, as long as formula (1) is satisfied, the effects of the present embodiment are not affected.

It is preferable that there be no anisotropy from the viewpoint of preventing wrinkling and distortion from occurring due to stress balance and of improving yield. Conversely, from the viewpoint of increasing air permeability and improving impregnation properties, it is preferable that L1 and L2 and/or W1 and W2 have anisotropy, and among these, it is preferable that the anisotropy value between L1 and L2 and the anisotropy value between W1 and W2 be different values.

The region satisfies formula (1). As a result, adhesion between filaments due to the sizing agent or silane coupling agent can be reduced, whereby a glass cloth with suitable resin impregnation properties can be realized. In order to control the bending rigidity of the glass cloth so as to satisfy formula (1), processing by dry ice blasting, bend processing with a low radius of curvature, etc., can be performed as the fiber-opening treatment.

Regarding the processing by dry ice blasting and the bend processing with a low radius of curvature, preferred embodiments thereof are as described below regarding the fiber-opening treatment method. According to a preferred embodiment as described below, bending rigidity can be easily adjusted within the range of formula (1).

### [Glass Type]

In the present embodiment, as the glass yarns (glass filaments) constituting the glass cloth, E-glass (alkali-free glass), which is generally used for printed wiring board applications; low dielectric constant glasses such as D glass, L glass, NE glass, L2 glass, silica glass, and quartz glass: high-strength glasses such as S glass and T glass; and high dielectric constant glasses such as H glass can be used. The glass yarns may be composed of one type of glass material, or may be a combination of two or more types of glass yarns composed of different glass materials.

### [Insertion Density/Interval]

In the present embodiment, the insertion density of the warp and weft yarns constituting the glass cloth is preferably 10 to 120 yarns/inch, and more preferably 40 to 100 yarns/inch. Specifically, the insertion intervals L1 and L2 of the warp and weft yarns constituting the glass cloth are each independently preferably 0.021 to 0.25 cm, more preferably 0.025 to 0.064 cm, and further preferably 0.030 to 0.055 cm.

### [Weave Structure of Glass Cloth]

In the present embodiment, examples of the weave structure of the glass cloth include plain weave, basket weave, satin weave, and twill weave. Among these, a plain weave structure is preferable.

### [Yarn Width]

In the present embodiment, the yarn width W1 of the warp yarns is preferably 0.015 to 0.055 cm, and more preferably 0.025 to 0.045 cm. Further, the yarn width W2 of weft yarns is preferably 0.030 to 0.070 cm, more preferably 0.034 to 0.060 cm, and further preferably 0.040 to 0.055 cm.

### [Thickness]

In the present embodiment, the thicknesses T1 and T2 of the glass cloth are each independently preferably 0.002 to 0.015 cm, 0.002 to 0.013 cm, or 0.003 to 0.013 cm, more preferably 0.0035 to 0.013 cm, more preferably 0.004 to 0.013 cm, and particularly preferably 0.0045 to 0.013 cm. Generally, the thicker the glass cloth, the worse the resin impregnation properties tend to be, i.e., the higher the demand for improvement of the resin impregnation properties tends to be. Note that the thickness of the glass cloth at the portion corresponding to the region described above can be treated as the thicknesses T1 and T2 of the region in formulas (1) and (2). Note that T1 and T2 have substantially the same value in the same predetermined region.

### [Number of Filaments]

The number of filaments is preferably 250 or less in warp yarns and in weft yarns. When the number of filaments is 250 or less, the thickness of the glass cloth can be easily reduced. From the viewpoint of the strength and handleability of the glass cloth, the number of filaments is preferably 30 or more, more preferably 40 or more, and further preferably 50 or more.

Furthermore, the number of filaments of warp yarns being the same as that of weft yarns means that the ratio of the number of filaments of weft yarns to the number of filaments of warp yarns (weft/warp ratio) is in the range of 0.94 or more and 1.06 or less.

### [Amount of Adhered Fine Particles]

A predetermined amount of fine particles may be adhered to the region described above.

The amount of fine particles adhered to the region is preferably 100 particles/μm or less. As a result, there is less burden on the environment and the human body as compared to conventional glass cloths, to which nanoparticles such as colloidal silica are adhered.

In order to obtain a region in which the amount of fine particles is 100 particles/μm or less, it is sufficient that a glass cloth in which the amount of fine particles is less than or equal to the above value be used. Such a glass cloth can be obtained via a production process that does not include a step in which fine particles may adhere to the glass cloth. Specifically, by producing the glass cloth without steps such as following:
a step of immersing the glass cloth in a liquid containing fine particles to carry out fiber-opening;
a step of using a liquid containing fine particles as a glass fiber sizing agent: or
a step of immersing the glass cloth in an aqueous dispersion of resin fine particles and elastomer fine particles;
it is possible to obtain glass cloth in which the amount of fine particles is less than or equal to the above value.

It is preferable that the amount of fine particles adhered to the region be 0 particles/μm. As a result, it becomes easier to realize a glass cloth which has a reduced load on the environment and the human body.

It is preferable that the fine particles have a size of 3 μm or less and be inorganic fine particles and/or organic fine particles. In particular, it is preferable that the inorganic fine particles be at least one selected from the group consisting of colloidal silica, crystalline silica, alumina, and boron nitride, and the organic fine particles be at least one selected from the group consisting of polyphenylene ether resins, epoxy resins, and styrene elastomers. As a result, it becomes easier to realize a glass cloth which has a reduced load on the environment and the human body.

### [Surface Treatment]

In the present embodiment, the glass yarns (including the glass filaments) of the glass cloth are surface-treated with a surface treatment agent. As a result, the reactivity with the matrix resin can be improved.

It is preferable that the surface treatment agent contain a silane coupling agent having a radical-reactive unsaturated double bond group (hereinafter also simply referred to as “silane coupling agent”). As a result, it becomes easier to improve the reactivity with the matrix resin. Furthermore, hydrophilic functional groups are less likely to be generated after reacting with the matrix resin, whereby insulation reliability is more likely to be improved.

As the surface treatment agent, it is preferable to use, for example, a silane coupling agent represented by the following general formula (2). By using such a silane coupling agent, moisture absorption resistance tends to be further improved, and as a result, insulation reliability tends to be further improved. Furthermore, it becomes easier to improve the reactivity with the matrix resin.

$${X ( R )}_{3 - n} S i {Y}_{n} \qquad ( 2 )$$

where X is an organic functional group having at least one unsaturated double bond group, each Y is independently an alkoxy group, n is an integer of 1 to 3, and each R is independently a group selected from the group consisting of a methyl group, an ethyl group, and a phenyl group.

Examples of the organic functional group having one or more unsaturated double bond groups represented by X include a vinyl group, an allyl group, a vinylidene group, an acryloxy group, and a methacryloxy group.

In general formula (2), the alkoxy group is preferably an alkoxy group having 5 or fewer carbon atoms in order for the glass cloth to be stably treated.

Examples of the silane coupling agent include known simple substances such as N-β-(N-vinylbenzylaminoethyl)-γ-aminopropyltrimethoxysilane and hydrochlorides thereof, N-β-(N-vinylbenzylaminoethyl)-γ-aminopropylmethyldimethoxysilane and hydrochlorides thereof, N-β-(N-di(vinylbenzyl)aminoethyl)-γ-aminopropyltrimethoxysilane and hydrochlorides thereof, N-β-(N-di(vinylbenzyl)aminoethyl)-N-γ-(N-vinylbenzyl)-γ-aminopropyltrimethoxysilane and hydrochlorides thereof, N-vinyltrimethoxysilane, methacryloxypropyltrimethoxysilane, and acryloxy propyltrimethoxysilane, and mixtures of these.

Though either water or an organic solvent can be used as the solvent for dissolving or dispersing the silane coupling agent, from the viewpoint of safety and protection of the global environment, it is preferable that water be used as the main solvent. As the method for obtaining a treatment liquid containing water as the main solvent, either a method in which the silane coupling agent is directly poured into water: or a method in which the silane coupling agent is dissolved in a water-soluble organic solvent to form an organic solvent solution, and the organic solvent solution is then poured into water is preferable.

Further, in order to improve the water dispersibility and stability of the silane coupling agent in the treatment liquid, a surfactant can also be used in combination.

### [Number of Fuzz]

Fuzz of 1 mm or more in the glass cloth is observed when a tension of 100 N/1000 mm is applied by Roll-to-Roll. The number of fuzz is preferably 10 pieces/m² or less, and more preferably 8 pieces/m² or less. The lower limit of the number of fuzz is ideally 0 pieces/m², but may be 1 piece/m² or more. From the viewpoint of ease of observation and measurement, the number of fuzz may be counted while irradiating with a halogen lamp.

### [Distortion Rate]

When the weft distortion rate is within the range of 4% or less, even if the glass cloth has a dielectric constant (Dk) of 5.0 or less and a thickness of 0.013 cm or less, it is possible to suppress or prevent the occurrence of tearing during the surface treatment step and prepreg production step. From this viewpoint, the weft distortion rate is more preferably 3%, further preferably 2% or less, and even further preferably 1% or less. Furthermore, the lower limit value of the weft distortion rate can be 0% or more, or can exceed 0%.

In general, measures to improve the resin impregnation properties of the glass cloth are carried out in the form of fiber opening processing on the glass cloth, such as a method using columnar flow or spray flow, a method using a vibro washer, or a method using high frequency vibration using a liquid as a medium. By increasing processing forces in these methods, the resin impregnation properties tend to improve. However, if the processing force in the fiber-opening step is excessively strong, fuzz and distortion tend to occur within the glass cloth. From the viewpoint of suppressing fuzz generation and distortion, it is preferable that excessively high processing force not be applied during fiber-opening.

### [Bending Rigidity]

In the present embodiment, a method for measuring the bending rigidity of the region in the glass cloth will be described with reference to FIGS. 1 and 2(a) to 2(d). FIG. 1 is a plan view of one surface of the region, and FIGS. 2(a) to 2(c) are views detailing the region bending operation. Note that FIGS. 1 and 2 show the operation during E1 measurement, and the operation when warp Lmd and weft Ltd are replaced in FIGS. 1 and 2 is the operation during E2 measurement.

The bending rigidity of the glass cloth can be measured using a “KES-FB2-A Bending Property Tester” manufactured by Kato Tech Co., Ltd. First, as shown in FIG. 1, a region 11 (test specimen) of warp direction Lmd×weft direction Ltd is taken from a glass cloth 10. The warp direction Lmd and weft direction Ltd may be the same or different. From the viewpoint of facilitating measurement of the bending rigidities E1 and E2, the warp direction Lmd and the weft direction Ltd can each be selected from 5 to 20 cm, and as an example, both can be selected to be 10 cm.

When measuring the bending rigidity E1, a chuck 12 grips the region 11 over the weft direction Ltd. Specifically, as the chuck 12, it is possible to use a chuck 12 composed of a first chuck part 12a and a second chuck part 12b facing each other substantially in parallel with a predetermined interval 13. The interval 13 is, for example, 1 cm.

It is preferable that each of the first chuck part 12a and second chuck part 12b grip over the weft direction Ltd so that the center 14 between the first chuck part 12a and the second chuck part 12b overlaps the center line 15 of the region 11.

As described above, the region 11 is gripped by the chuck 12 (refer to FIG. 2(a)), and a constant velocity curvature pure bending test is performed in the range of a curvature K=−2.5 to +2.5 (cm⁻¹). The deformation speed can be 0.50 (cm⁻¹/sec).

First bending: bending from K=0 to K=+2.5 so that one surface 11A of the region 11 becomes a “valley” (refer to FIG. 2(b)).

Second bending: bending from K=+2.5, through K=0, to K=−2.5 so that the other surface 11B of the region 11 becomes a “valley” (refer to FIG. 2(c)).

Third bending: bending from K=−2.5, through K=0, to K=+2.5 so that the one surface 11A of the region 11 becomes a “valley” (refer to FIG. 2(b)).

In the first bending and the third bending, the one surface 11A of the region 11 is bent so as to become a valley, and in the second bending, the other surface 11B of the region 11 is bent so as to become a valley, whereby the bending rigidity E1 of the region 11 is measured.

When measuring E1, in the first bending, second bending, and third bending, warp yarns derived from the warp yarns of the glass cloth 10 in the region 11 are bent.

In the first bending, the second bending, and the third bending, bending is carried out so as to create a valley that forms a valley bottom line 16 along the weft direction Ltd originating from the weft yarns of the glass cloth 10 (in parallel to the weft direction Ltd).

In particular, in the first bending, second bending, and third bending, bending is preferably carried out so as to create a valley that forms a valley bottom line 16 overlapping with the center line 15 of the region 11.

In the “third bending”, the bending rigidity E1 obtained in the range from K=0.5 to K=+1.5 is measured. The unit is N·cm²/cm. The measurement environment can be approximately 25° C. and approximately 60% RH.

When measuring the bending rigidity E2, the warp direction Lmd and the weft direction Ltd when measuring the bending rigidity E1 are replaced, and in the first bending, second bending, and third bending, weft yarns derived from the weft yarns of the glass cloth 10 in region 11 are bent.

In the first bending, the second bending, and the third bending, bending is carried out so as to create a valley that forms a valley bottom line 16 along the warp direction Lmd originating from the warp yarns of the glass cloth 10 (in parallel to the warp direction Lmd).

### [Loss on Ignition Value]

In the present embodiment, the loss on ignition value of the glass cloth is preferably 0.10 to 1.20% by mass, more preferably 0.11 to 1.10% by mass, and further preferably 0.12 to 1.00% by mass. By setting the loss on ignition value to 0.10 to 1.20% by mass, the resin impregnation properties can be secured and heat resistance can be imparted. The “loss on ignition value” as used herein can be measured in accordance with the method described in JIS R 3420. Specifically, first, the glass cloth is arranged in a dryer at 110° C. and dried for 60 minutes. After drying, the glass cloth is transferred to a desiccator, allowed to stand for 20 minutes, and allowed to cool to room temperature. After cooling, the mass (first mass) of the glass cloth is measured in a unit of 0.1 mg or less. Next, the glass cloth is heated in a muffle furnace at 625° C. for 20 minutes. After heating in a muffle furnace, the glass cloth is transferred to a desiccator, allowed to stand for 20 minutes, and allowed to cool to room temperature. After cooling, the mass (second mass) of the glass cloth is measured in a unit of 0.1 mg or less. The difference between the first mass and the second mass is obtained as the loss on ignition value. The amount of silane coupling agent with which the glass cloth is treated is defined in accordance with the loss on ignition value determined by the above measurement method.

### [Glass Cloth Production Method]

The glass cloth production method according to the present embodiment comprises, for example,
a weaving step of weaving glass yarns to obtain a glass cloth,
a de-sizing step of removing a sizing agent adhered to the glass yarns of the glass cloth,
a surface treatment step with a silane coupling agent or the like, and
a fiber-opening step of performing fiber-opening of the glass yarns of the glass cloth.

In the weaving method, the weft and warp yarns can be woven into a predetermined weave structure.

Examples of the de-sizing method include a method of removing a sizing agent by heating. Note that the sizing agent is used for the purpose of protecting the glass yarns from breakage during the weaving step and the like. Examples of such sizing agents include starch binders and polyvinyl alcohol binders. Starch binders and the polyvinyl alcohol binders contain at least starch and polyvinyl alcohol, respectively, and may be a mixture with waxes.

The temperature at which the sizing agent is removed by heating (heat cleaning) is preferably 300 to 550° C., more preferably 350 to 480° C., and further preferably 370 to 450° C. from the viewpoint of sufficiently removing the sizing agent while maintaining breaking strength.

The heating time may be appropriately adjusted in accordance with conditions such as the heating temperature and the thickness of the glass cloth, and from the viewpoint of sufficiently removing the sizing agent while maintaining breaking strength, is preferably 20 to 80 hours, more preferably 25 to 70 hours, and further preferably 30 to 60 hours.

In the de-sizing step, in which the sizing agent adhered to the glass yarns of the glass cloth is removed, before and/or after the sizing agent is removed by heating, the sizing agent before heating and/or combustion residue adhering to the surface of the glass cloth after heating can be removed by washing with water.

Furthermore, examples of the surface treatment method include a method in which a surface treatment agent containing a silane coupling agent at a concentration of 0.1 to 3.0% by mass is brought into contact with the glass cloth, which is then dried. Note that the surface treatment agent can be brought into contact with the glass cloth by immersing the glass cloth in the surface treatment agent, or by applying the surface treatment agent to the glass cloth using a roll coater, die coater, gravure coater, etc. Examples of the method for drying the surface treatment agent include hot air drying and drying methods using electromagnetic waves.

Further, examples of the fiber-opening treatment method include processing by dry ice blasting; and bend processing with a low radius of curvature. The fiber-opening treatment may be performed simultaneously with weaving or after weaving. The fiber-opening treatment may be performed before or after heat cleaning, or at the same time as heat cleaning, or at the same time as or after a surface treatment, which will be described later.

In combination with the processing by dry ice blasting: or bend processing with a low radius of curvature, there may be performed a fiber-opening treatment in which water pressure is applied to the glass cloth: a fiber-opening treatment using high frequency vibration using water (for example, de-aerated water, ion-exchanged water, deionized water, electrolyzed cation water, electrolyzed anion water, etc.) as a medium; and processing by pressure using rollers.

Dry ice blast processing is a method in which fine particles of dry ice having a particle size of 5 to 300 μm are jetted (sprayed) from a height of 5 to 1000 mm at an air pressure of 0.05 to 1 MPa. A more preferable method is to spray fine particles of dry ice having a particle size of 5 to 300 μm from a height of 5 mm to 600 mm at an air pressure of 0.1 to 0.5 MPa. Within this range, the effect of improving the impregnation properties can be expected without causing quality problems such as glass yarn breakage.

The bend processing is a method of performing fiber-opening processing via 2 or more, and preferably 10 times or more passages through rollers having a radius of curvature of R=2.5 mm or less, preferably a radius of curvature of R=2.0 mm or less. When the radius of curvature R is 2.5 mm or less, adhesion between filaments caused by the sizing agent and the silane coupling agent can be sufficiently removed, whereby the effect of improving impregnation properties can be expected.

### [Prepreg]

The prepreg according to the present embodiment comprises the low dielectric glass cloth described above and a matrix resin composition, with which the low dielectric glass cloth is impregnated. The prepreg having the above-mentioned glass cloth has a high adhesion with the resin, and the yield of the final product is high. Furthermore, as an effect which can be brought about, it is possible to provide a printed wiring board which has excellent dielectric properties and excellent resistance to moisture absorption, whereby fluctuations in dielectric constant are small under the influence of the usage environment, in particular, in high humidity environments.

The prepreg of the present embodiment can be produced by a conventional method. For example, it can be produced by impregnating the glass cloth of the present embodiment with a varnish made by diluting a matrix resin such as an epoxy resin with an organic solvent, volatilizing the organic solvent in a drying oven, and curing the thermosetting resin to a B-stage state (semi-cured state).

As the matrix resin, either a thermosetting resin or a thermoplastic resin can be used. The thermosetting resin is not particularly limited, and examples thereof include:
a) an epoxy resin which is obtained by reacting and curing a compound having an epoxy group, and a compound having at least one of an amino group, a phenol group, an acid anhydride group, a hydrazide group, an isocyanate group, a cyanate group, and a hydroxyl group that react with the epoxy group without a catalyst or with an added catalyst having reaction catalytic ability such as an imidazole compound, tertiary amine compound, urea compound, or phosphorus compound;
b) a radical polymerization curing resin obtained by curing a compound having at least one of an allyl group, a methacrylic group, and an acrylic group using a thermal decomposition catalyst or a photodecomposition catalyst as a reaction initiator;
c) a maleimide triazine resin obtained by reacting and curing a compound having a cyanate group and a compound having a maleimide group;
d) a thermosetting polyimide resin obtained by reacting and curing a maleimide compound and an amine compound; and
e) a benzoxazine resin obtained by crosslinking and curing a compound having a benzoxazine ring via heat polymerization.

The thermoplastic resin is not particularly limited, and examples thereof include polyphenylene ether, modified polyphenylene ether, polyphenylene sulfide, polysulfone, polyether sulfone, polyarylate, aromatic polyamide, polyether ether ketone, thermoplastic polyimides, insoluble polyimides, polyamideimides, and fluororesins. Furthermore, a thermosetting resin and a thermoplastic resin may be used together.

### [Printed Wiring Board]

The printed wiring board of the present embodiment comprises the prepreg described above. Specifically, the printed wiring board of the present embodiment comprises the glass cloth described above and a cured product of a matrix resin composition, with which the glass cloth described above is impregnated. The printed wiring board of the present embodiment has a high adhesion to the resin, and the yield of the final product is high. Furthermore, since it has excellent dielectric properties and moisture absorption resistance, it can also exhibit the effect wherein fluctuations in the dielectric constant are small under the influence of the usage environment, in particular, in high humidity environments. Since the glass cloth described above is used, it is possible to realize a product with fewer voids, which has less impact on the environment and the human body, and has suitable impregnation properties with the low dielectric resin.

### EXAMPLES

The present invention will be specifically described below based on Examples.

### Example 1

An L glass cloth (style 1078: average filament diameter 5 μm, warp insertion density 54 yarns/inch, weft insertion density 54 yarns/inch, thickness 0.0046 cm) was prepared. The prepared glass cloth was subjected to a de-oiling treatment, a surface treatment, and a fiber-opening treatment to obtain glass cloth 1.

As the de-oiling treatment, a treatment in which the glass cloth was arranged in a heating furnace at an ambient temperature of 350° C. to 400° C. for 60 hours in order to thermally decompose the spinning and weaving sizing agents adhered to the glass cloth was used.

After the de-oiling treatment, the glass cloth was subjected to surface treatment using a silane coupling agent. Methacryloxypropyltrimethoxysilane (manufactured by Dow Corning Toray Industries, Inc.: Z6030) was used as the silane coupling agent and dispersed in water to obtain a treatment solution and the glass cloth was immersed therein. Then, the glass cloth was squeezed to remove the liquid and then dried. As a result of the above treatment, the glass cloth was treated with the silane coupling agent (surface treatment).

As the fiber-opening treatment, a treatment in which fiber-opening processing was performed by spraying fine particles of dry ice having a particle size of 5 to 50 μm at an air pressure of 0.4 MPa was used.

Using the evaluation method described below, the converted bending rigidity “(E1/T1)/(W1/L1)” was calculated, and it was confirmed that the predetermined region of the glass cloth 1 satisfied formula (1), i.e., the glass cloth of the present Example was obtained.

### Example 2

Glass cloth 2 was obtained in the same manner as in Example 1, except that as the fiber-opening treatment, a fiber-opening processing by bending the glass cloth 10 times with a radius of curvature R=1 mm was performed. Using the evaluation method described below, the converted bending rigidity “(E1/T1)/(W1/L1)” was calculated, and it was confirmed that the predetermined region of the glass cloth 2 satisfied formula (1), i.e., the glass cloth of the present Example was obtained.

### Example 3

Glass cloth 3 was obtained in the same manner as in Example 1, except that an L glass cloth (style 3313: average filament diameter 6 μm, warp insertion density 60 yarns/inch, weft insertion density 62 yarns/inch, thickness 0.0073 cm) was used. Using the evaluation method described below, the converted bending rigidity “(E1/T1)/(W1/L1)” was calculated, and it was confirmed that the predetermined region of the glass cloth 3 satisfied formula (1), i.e., the glass cloth of the present Example was obtained.

### Example 4

Glass cloth 4 was obtained in the same manner as in Example 2, except that an L glass cloth (style 3313: average filament diameter 6 μm, warp insertion density 60 yarns/inch, weft insertion density 62 yarns/inch, thickness 0.0073 cm) was used. Using the evaluation method described below, the converted bending rigidity “(E1/T1)/(W1/L1)” was calculated, and it was confirmed that the predetermined region of the glass cloth 4 satisfied formula (1), i.e., the glass cloth of the present Example was obtained.

### Example 5

Glass cloth 5 was obtained in the same manner as in Example 1, except that an L glass cloth (style 2116: average filament diameter 7 μm, warp insertion density 60 yarns/inch, weft insertion density 58 yarns/inch, thickness 0.0093 cm) was used, and the fiber-opening treatment was performed using fine particles of dry ice of 10 to 200 μm. Using the evaluation method described below, the converted bending rigidity “(E1/T1)/(W1/L1)” was calculated, and it was confirmed that the predetermined region of the glass cloth 5 satisfied formula (1), i.e., the glass cloth of the present Example was obtained.

### Example 6

Glass cloth 6 was obtained in the same manner as in Example 2, except that an L glass cloth (style 2116: average filament diameter 7 μm, warp insertion density 60 yarns/inch, weft insertion density 58 yarns/inch, thickness 0.0093 cm) was used. Using the evaluation method described below, the converted bending rigidity “(E1/T1)/(W1/L1)” was calculated, and it was confirmed that the predetermined region of the glass cloth 6 satisfied formula (1), i.e., the glass cloth of the present Example was obtained.

### Comparative Example 1

A glass cloth was obtained in the same manner as in Example 1, except that the fiber-opening processing was performed using a columnar flow discharged from a 0.9 MPa high-pressure water spray. Using the evaluation method described below, the converted bending rigidity “(E1/T1)/(W1/L1)” was calculated.

### Comparative Example 2

A glass cloth was obtained in the same manner as in Example 3, except that the fiber-opening processing was performed using a columnar flow discharged from a 1.4 MPa high-pressure water spray. Using the evaluation method described below, the converted bending rigidity “(E1/T1)/(W1/L1)” was calculated.

### Comparative Example 3

A glass cloth was obtained in the same manner as in Example 5, except that the fiber-opening processing was performed using a columnar flow discharged from a 1.7 MPa high-pressure water spray. Using the evaluation method described below, the converted bending rigidity “(E1/T1)/(W1/L1)” was calculated.

### [Measurement and Evaluation]

Various measurements and evaluations were performed on each of the glass cloths of the Examples and Comparative Examples.

### (Thickness Measurement)

The thicknesses T1 and T2 of the glass cloths were measured as follows.

In accordance with 7.10 of JIS R3420, a micrometer was used, the spindle was gently rotated to make a light contact with the measurement surface in parallel, and the scale was read after the ratchet made three sounds. Note that JIS R3420 stipulates a general testing method for continuous glass fibers and products such as glass cloths using continuous glass fibers.

### (Warp and Weft Insertion Intervals)

By measuring the number of glass yarns per inch using a microscope, the insertion density (glass yarns/inch) was obtained, and based on this, the warp and weft insertion intervals were obtained. The value obtained for the warp yarns was used as insertion interval L1 (cm) in formula (1). Furthermore, the value obtained for the weft yarns was used as insertion interval L2 (cm) in formula (2).

### (Measurement of Yarn Width)

Yarn width was measured using a high-precision camera. Specifically, the yarn width was determined by observing a portion of the glass cloth having a size of 100 mm×100 mm or more at an arbitrary position. The value obtained for the warp yarns was used as the yarn width W1 (cm) in formula (1). Further, the value obtained for the weft yarns was used as the yarn width W2 (cm) in formula (2).

### (Measurement of Bending Rigidity)

The bending rigidity of the glass cloth was measured using a “KES-FB2-A bending property tester” manufactured by Kato Tech Co., Ltd. First, a test specimen (corresponding to the “region” of claim 1) measuring 10 cm in the warp direction and 10 cm in the weft direction was taken from each of the glass cloths of the Examples and Comparative Examples. Then, the test specimen was gripped by a chuck over a weft direction of 10 cm. The chuck specifically used was a chuck composed of a first chuck part and a second chuck part facing each other substantially in parallel with an interval of 1 cm. The test specimen was gripped by both the first chuck part and the second chuck part, over a weft direction of 10 cm so that the center between the first chuck part and the second chuck part overlapped the center line of the test specimen (refer to FIGS. 1 and 2(a)).

The test specimen was gripped by the chuck as described above, and a constant velocity curvature pure bending test was conducted in the range of curvature K=−2.5 to +2.5 (cm⁻¹). The deformation speed was 0.50 (cm⁻¹/sec).

First bending: bending from K=0 to K=+2.5 so that one surface of the test specimen became a “valley” (refer to FIG. 2(b)).

Second bending: bending from K=+2.5, through K=0, to K=−2.5 so that the other surface of the test specimen became a “valley” (refer to FIG. 2(c)).

Third bending: bending from K=−2.5, through K=0, to K=+2.5 so that the one surface of the test specimen became a “valley” (refer to FIG. 2(b)).

In the first bending, second bending, and third bending, warp yarns derived from the warp yarns of the glass cloth of the test specimen were bent. Specifically, in the first bending, second bending, and third bending, bending was carried out so as to create a valley that formed a valley bottom line along the weft direction originating from the weft yarns of the glass cloth. More specifically, in the first bending, second bending, and third bending, bending was carried out so as to create a valley that formed a valley bottom line overlapping with the center line of the test specimen.

In the “third bending,” the bending rigidity obtained in the range from K=0.5 to K=+1.5 was measured as the second repetition bending rigidity. The obtained value was used as the second repetition bending rigidity E1 (N·cm²/cm) of formula (1).

Furthermore, in the same manner, weft yarns derived from the weft yarns of the glass cloth were bent, specifically, in the first bending, second bending, and third bending, bending was carried out so as to create a valley that formed a valley bottom line along the warp direction originating from the warp yarns of the glass cloth, and more specifically, in the first bending, second bending, and third bending, bending was carried out so as to create a valley that formed a valley bottom line overlapping with the center line of the test specimen. In the “third bending,” the bending rigidity obtained in the range from K=0.5 to K=+1.5 was measured as the second repetition bending rigidity, and the obtained value was used as the bending rigidity E2 (N·cm²/cm) in formula (2). Note that the measurement environment was approximately 25° C. and approximately 60% RH.

Note that the phrase “second repetition” of “during a second repetition of bending” in the present embodiment is used with the intention of the second repetition of “bending to increase the curvature K.”

In the process of:
the first bending (from K=0) to K=+2.5);
second bending (from K=+2.5, through K=0), to K=−2.5); and
third bending (from K=−2.5, through K=0, to K=+2.5);
the rigidity in the range of K=0.5 to K=+1.5 in the “third bending” to increase the curvature K in the second repetition corresponds to the “second repetition bending rigidity” of the present embodiment.

### (Evaluation of Resin Impregnation Properties)

A glass cloth was sampled so as to have a size of 50 mm×50 mm or more. At this time, sampling was performed without bending or touching the measurement location. Evaluation was performed by counting the number of voids when the sampled glass cloth was impregnated with castor oil (manufactured by Hayashi Pure Chemical Industries, Ltd.) at a liquid temperature of 24 to 26° C. for a predetermined period of time. A high-precision camera (frame size: 5120×5120 pixels) was installed perpendicular to the glass cloth. LED lights (power flash bar type lighting manufactured by CCS Co., Ltd.) as a light source were then arranged 15 cm away from the glass cloth so that the glass cloth was interposed therebetween from the sides. Both sides of the glass cloth were then irradiated.

At a viewing angle of 32 mm×32 mm, the number of voids of 160 μm or more present between glass filaments was measured using a high-precision camera (frame size: 5120×5120 pixels). Measurement was performed three times and the average value was taken as the number of voids. Voids correspond to portions which are unimpregnated with the matrix resin. Thus, a small number of voids in the glass cloth means that the glass cloth has excellent impregnation properties with the matrix resin.

### (Measurement of Amount of Adhered Fine Particles)

Preparation for measurement was carried out by attaching a glass cloth cut into a 4 cm square size to a sample stand using carbon double-sided tape. Using a KEYENCE VHX-D500, an operation of observing 1325 μm each along the warp and weft yarns was performed five times in total, and the frequency of granular foreign particles adhering to the glass cloth was determined from the number and the observed length of counted granular foreign particles. From the obtained frequency, the amount of adhered fine particles (particles/μm) was determined.

### <Measurement Conditions>

Measurement mode: ultra-depth observe mode
Magnification: 1000×
Preset: 25 mm

### (Distortion Rate Measurement)

The distortion rate was measured as follows. First, the distortion amount of a sample was measured in accordance with JIS L1096. Specifically, one weft yarn in a 1000 mm wide glass cloth stretched on a pair of rollers was visually observed, and using the TD tangent between the rollers and the cloth as a reference line, the amount of displacement from the reference line was measured. The difference between the maximum value and the minimum value of the amount of displacement was calculated as the amount of distortion, and this operation was performed five times to calculate the average value.

The weft distortion rate was then calculated from the distortion amount relative to the roller width. The weft distortion rate was calculated using the following formula:

Weft distortion rate (%)={(distortion amount)/(roller width)}×100

### (Glass Cloth Fuzz Evaluation)

The glass cloths obtained in the above Examples and Comparative Examples were subjected to a tension of 100 N/1000 mm on a Roll-to-Roll inspection table. The number of fuzz (projections) of 1 mm or more per m² (pieces/m²) was determined by visual observation while irradiating with a halogen lamp.

### (Calculation of Converted Bending Rigidity)

Using the values obtained above, the converted bending rigidity was calculated according to each of formulas (1) and (2). Note that in each of the Examples and Comparative Examples, the same values were used for the thicknesses T1 and T2.

### (Preparation of Prepreg and Printed Wiring Board)

Using the glass cloths of the Examples, a prepreg and a printed wiring board could be produced by a conventional method, and it was confirmed that the prepreg and printed wiring board exhibited the desired functions.

The results of the Examples and Comparative Examples are shown in Table 1.

TABLE 1

| | Ex 1 | Ex 2 | Ex 3 | Ex 4 | Ex 5 |
|---|---|---|---|---|---|
| Style | L1078 | L1078 | L3313 | L3313 | L2116 |
| Thicknesses T1 (cm) and T2 (cm) | 0.0046 | 0.0046 | 0.0073 | 0.0073 | 0.0093 |
| Second repetition bending rigidity | 0.000153 | 0.00016 | 0.000479 | 0.000536 | 0.001011 |
| E1 (N · cm²/cm) | | | | | |
| Warp insertion interval L1 (cm) | 0.470 | 0.470 | 0.423 | 0.423 | 0.423 |
| Warp width W1 (cm) | 0.30 | 0.30 | 0.35 | 0.35 | 0.40 |
| Warp converted bending rigidity | 0.052 | 0.055 | 0.079 | 0.089 | 0.115 |
| (E1/T1)/(W1/L1) | | | | | |
| Amount of adhered particles (particles/um) | 0 | 0 | 0 | 0 | 0 |
| Number of fuzz (pieces/m²) | 3 | 1 | 2 | 0 | 2 |
| Distortion rate (%) | 1 | 2 | 1 | 2 | 1 |
| Number of filaments (filaments) | 200 | 200 | 200 | 200 | 200 |
| Second repetition bending rigidity | 0.000153 | 0.00016 | 0.000479 | 0.000536 | 0.001011 |
| E2 (N · cm²/cm) | | | | | |
| Weft insertion interval L2 (cm) | 0.470 | 0.470 | 0.410 | 0.410 | 0.438 |
| Weft width W2 (cm) | 0.48 | 0.48 | 0.43 | 0.43 | 0.45 |
| Warp converted bending rigidity | 0.033 | 0.034 | 0.063 | 0.070 | 0.106 |
| (E2/T2)/(W2/L2) | | | | | |
| Number of voids (voids) | 5 | 60 | 2 | 5 | 22 |
| Fiber-opening treatment | Fine particles | Bending | Fine particles | Bending | Fine particles |
| | of dry ice | R = 1 mm | of dry ice | R = 1 mm | of dry ice |

| | | Comp | Comp | Comp |
|---|---|---|---|---|
| | Ex 6 | Ex 1 | Ex 2 | Ex 3 |
| Style | L2116 | L1078 | L3313 | L2116 |
| Thicknesses T1 (cm) and T2 (cm) | 0.0093 | 0.0046 | 0.0073 | 0.0093 |
| Second repetition bending rigidity | 0.000874 | 0.000499 | 0.001051 | 0.001319 |
| E1 (N · cm²/cm) | | | | |
| Warp insertion interval L1 (cm) | 0.423 | 0.470 | 0.423 | 0.423 |
| Warp width W1 (cm) | 0.40 | 0.30 | 0.35 | 0.40 |
| Warp converted bending rigidity | 0.110 | 0.170 | 0.174 | 0.150 |
| (E1/T1)/(W1/L1) | | | | |
| Amount of adhered particles (particles/um) | 0 | 0 | 0 | 0 |
| Number of fuzz (pieces/m²) | 0 | 3 | 3 | 3 |
| Distortion rate (%) | 2 | 2 | 2 | 2 |
| Number of filaments (filaments) | 200 | 200 | 200 | 200 |
| Second repetition bending rigidity | 0.000874 | 0.000250 | 0.000526 | 0.000660 |
| E2 (N · cm²/cm) | | | | |
| Weft insertion interval L2 (cm) | 0.438 | 0.470 | 0.410 | 0.438 |
| Weft width W2 (cm) | 0.45 | 0.48 | 0.43 | 0.45 |
| Warp converted bending rigidity | 0.091 | 0.053 | 0.069 | 0.069 |
| (E2/T2)/(W2/L2) | | | | |
| Number of voids (voids) | 13 | 442 | 476 | 782 |
| Fiber-opening treatment | Bending | Columnar flow | Columnar flow | Columnar flow |
| | R = 1 mm | | | |

### DESCRIPTION OF REFERENCE SIGNS

10: glass cloth
11: region (predetermined region in glass cloth)
11A: one surface
11B: other surface
12: chuck
12a: first chuck part
12b: second chuck part
13: interval
14: center between first chuck part and second chuck part
15: center line of region
16: valley bottom line
Lmd: warp direction
Ltd: weft direction

1. A glass cloth comprising glass yarns composed of a plurality of glass filaments, woven as warp and weft yarns, and surface-treated with a surface treatment agent, wherein
the glass cloth contains a predetermined region, and
in the region, the following formula (1) is greater than 0 and 0.14 or less:
$$( E 1 / T 1 ) / ( W 1 / L 1 ) \qquad ( 1 )$$
where E1 represents a second repetition bending rigidity (N·cm²/cm) per unit length between curvatures of 0.5 and +1.5 cm⁻¹ during a second repetition of bending with a curvature of 2.5 cm⁻¹,
T1 represents a thickness (cm) of the region,
L1 represents an insertion interval (cm) of the warp yarns,
W1 represents a warp width (cm), and
bending is carried out so as to create a valley that forms a valley bottom line along a weft direction.

2. The glass cloth according to claim 1, wherein the formula (1) is greater than 0 and 0.13 or less.

3. The glass cloth according to claim 1, wherein the thickness T1 of the region is 0.002 to 0.013 cm.

4. The glass cloth according to claim 1, wherein the insertion interval L1 of the warp yarns is 0.021 to 0.25 cm.

5. The glass cloth according to claim 1, wherein an amount of fine particles adhered to the region is 100 particles/μm or less.

6. The glass cloth according to claim 1, wherein the surface treatment agent contains a silane coupling agent having a radical-reactive unsaturated double bond.

7. The glass cloth according to claim 1, wherein a number of fuzz having a length of 1 mm or more observed when a tension of 100 N/1000 mm is applied by roll-to-roll is 10 pieces/m² or less, and a weft distortion rate is 4% or less.

8. The glass cloth according to claim 1, wherein the glass cloth contains a region where the following formula (2) satisfies greater than 0 and 0.14 or less:
$$( E 2 / T 2 ) / ( W 2 / L 2 ) \qquad ( 2 )$$
wherein E2 represents a second repetition bending rigidity (N·cm²/cm) per unit length between curvatures of 0.5 and +1.5 cm⁻¹ during a second repetition of bending with a curvature of 2.5 cm⁻¹,
T2 represents a thickness (cm) of the region,
L2 represents an insertion interval (cm) of the weft yarns,
W2 represents a weft width (cm), and
bending is carried out so as to create a valley that form a valley bottom line along a warp direction.

9. The glass cloth according to claim 8, wherein the formula (2) is greater than 0 and 0.13 or less.

10. The glass cloth according to claim 8, wherein the thickness T2 of the region is 0.002 to 0.013 cm.

11. The glass cloth according to claim 8, wherein the insertion interval L2 of the weft yarns is 0.021 to 0.25 cm.

12. The glass cloth according to claim 1, wherein an amount of fine particles adhered to the region is 0 particles/μm.

13. The glass cloth according to claim 12, wherein the fine particles are inorganic fine particles and/or organic fine particles having a diameter of 3 μm or less.

14. The glass cloth according to claim 13, wherein the inorganic fine particles are at least one selected from the group consisting of colloidal silica, crystalline silica, alumina, and boron nitride, and
the organic fine particles are at least one selected from the group consisting of a polyphenylene ether resin, an epoxy resin, and a styrenic elastomer.

15. A prepreg, comprising the glass cloth according to claim 1, and a matrix resin composition, with which the glass cloth is impregnated.

16. A printed wiring board, comprising the glass cloth according to claim 1, and a cured product of a matrix resin composition, with which the glass cloth is impregnated.

17. A glass cloth production method, for the production of the glass cloth according to claim 1, comprising the step of:
spraying fine particles of dry ice to perform fiber-opening.

18. The glass cloth production method according to claim 17, wherein the fiber-opening is performed by bending with a radius of curvature of 2.5 mm or less.
